(19) United States
(12) Patent Application Publication
(10) Pub. No.: US 2024/0218496 A1
(43) Pub. Date: Jul. 4, 2024

(54) EVAPORATION SOURCE DEVICE AND EVAPORATION SOURCE SYSTEM

(71) Applicant: WUHAN CHINA STAR OPTOELECTRONICS SEMICONDUCTOR DISPLAY TECHNOLOGY CO., LTD., Wuhan, Hubei (CN)

(72) Inventors: Liang Sun, Wuhan, Hubei (CN); Jun Yang, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/758,220

(22) PCT Filed: May 23, 2022
(86) PCT No.: PCT/CN2022/094413

§ 371 Date: Nov. 16, 2023

(30) Foreign Application Priority Data
May 13, 2022 (CN) 202210522023.3

(51) Int. Cl. C23C 14/24

(52) U.S. Cl. CPC C23C 14/243

(57) ABSTRACT

An evaporation source device is provided by the present application. The evaporation source device includes a vacuum chamber, and a pedestal, at least one vacuum box, and at least one control valve that are disposed in the vacuum chamber; and the at least one vacuum box is disposed on the pedestal, and a crucible is disposed in the vacuum box; the vacuum box is connected with the control valve; wherein the control valve includes a first nozzle and a second nozzle disposed oppositely, the first nozzle communicates with the vacuum box, and the second nozzle communicates with the vacuum chamber.

### BACKGROUND OF INVENTION

### Field of Invention

The present application relates to the field of display technology, and in particular to an evaporation source device and an evaporation source system.

### Description of Prior Art

In recent years, organic light-emitting diode (OLED) display technology has developed explosively in consumer applications such as mobile phones, computers, televisions, and vehicles, and commercial OLED display devices mainly include three-color OLED display devices of red (R), green (G), and blue (B), and white OLED display devices with color filters. The OLED display technology mainly includes a small-molecule OLED display technology based on vacuum evaporation technology and a polymer OLED display technology based on solution processes. Evaporator is a main production equipment for small-molecule OLED display devices that have been mass-produced, and a core part thereof is an evaporation source device. An existing evaporation source device generates heat by energizing a heating source, thereby heating and gasifying a crucible and a material placed in the crucible to form an evaporation source; the evaporation source is deposited as a thin film after reaching a substrate.

The evaporation source device in the prior art has following shortcomings: 1. an amount of gas generated by evaporation of a material used in an evaporation process is uncontrollable, and the material evaporates too fast, resulting in a decrease in a vacuum degree in a vacuum chamber; that is, a vacuum environment becomes worse, which affects quality of a coating film and eventually leads to a poor luminous effect of the material; 2. in a process of continuous heating, an evaporation rate of the material jumps, occasionally accompanied by splashing of a raw material; 3. due to a large gas flow and an uneven reaction, white particles (about 10 microns) visible to a naked eye appear in a thin film formed by evaporation, which increases roughness of the thin film. Therefore, it is necessary to improve this defect.

### SUMMARY OF INVENTION

Embodiments of the present application provides an evaporation source device, which is used to solve a technical problem that an gas flow of an evaporation coating of an evaporation source device in the prior art is uncontrollable and a material evaporates too fast, which leads to a decrease in a vacuum degree in a vacuum chamber and affects quality of a coating film; in addition, and used to solve a technical problem of a raw material splashes during an evaporation process and roughness of a thin film formed by evaporation is too high.

The embodiments of the present application provides an evaporation source device, including a vacuum chamber, and a pedestal, at least one vacuum box, and at least one control valve which are located in the vacuum chamber; at least one of the vacuum boxes is disposed on the pedestal, and a crucible is disposed in the vacuum box; the vacuum box is connected with the control valve; wherein, the control valve includes a first nozzle and a second nozzle disposed oppositely, the first nozzle communicates with the vacuum box, and the second nozzle communicates with the vacuum chamber.

The embodiments of the present application provides an evaporation source system, including an evaporation source device and a substrate placed in the evaporation source device; the evaporation source device includes a vacuum chamber, and a pedestal, at least one vacuum box, and at least one control valve which are located in the vacuum chamber; at least one of the vacuum boxes is disposed on the pedestal, and a crucible is disposed in the vacuum box; the vacuum box is connected with the control valve; wherein, the control valve includes a first nozzle and a second nozzle disposed oppositely, the first nozzle communicates with the vacuum box, and the second nozzle communicates with the vacuum chamber.

### Advantageous Effects

The embodiments of the present application provide the evaporation source device that includes the vacuum chamber and the pedestal, at least one vacuum box, and at least one control valve which are located in the vacuum chamber; at least one of the vacuum boxes is disposed on the pedestal, and the crucible is disposed in the vacuum box; the vacuum box is connected with the control valve; wherein, the control valve includes the first nozzle and the second nozzle disposed oppositely, the first nozzle communicates with the vacuum box, and the second nozzle communicates with the vacuum chamber. In the present application, by setting the crucible in the vacuum box, splashing raw materials can be prevented from being evaporated to the substrate; by allowing an evaporation source generated in the vacuum box to enter the vacuum chamber through the control valve, the gas flow can be controlled by changing an opening and closing degree of the control valve, so as to control a thickness of the coating film at all times during an evaporation coating process and improve the quality of the coating film; it can also make the raw materials react uniformly and prevent generation of white particles from affecting the roughness of the thin film.

### BRIEF DESCRIPTION OF DRAWINGS

FIG. 1 is a basic structural schematic diagram of an evaporation source device provided by an embodiment of the present application.

FIG. 2 is a cross-sectional view of a vacuum box provided by an embodiment of the present application.

FIG. 3 is a schematic diagram of placing a graphite block on a crucible provided by an embodiment of the present application.

FIG. 4 is a side view of a vacuum box placed in a vacuum chamber provided by an embodiment of the present application.

FIG. 5 is a top view of the vacuum box placed in the vacuum chamber provided by the embodiment of the present application.

### DETAILED DESCRIPTION OF PREFERRED EMBODIMENTS

The technical solutions in the embodiments of the present application will be clearly and completely described below with reference to the accompanying drawings in the embodiments of the present application. In the drawings, for clarity and ease of understanding and description, dimensions and thicknesses of components depicted in the drawings are not to scale.

It should be noted that in evaporation source devices of the prior art, a crucible is placed in a vacuum chamber directly, and vapor generated by heating the crucible is directly coated in the vacuum chamber; a reaction rate in the vacuum chamber is fast at a beginning, and a large amount of gas will be generated; as a result, a vacuum degree in the vacuum chamber is greatly reduced, resulting in a poor vacuum environment, which will affect quality of a coating film; and in a process of continuous heating, raw materials in the crucible may splash; in addition, due to a fast reaction rate and a non-uniform reaction, white particles are also generated, which adhere to a substrate, resulting in roughness of a thin film formed by evaporation being too high. The embodiments of the present application can solve the above-mentioned defects.

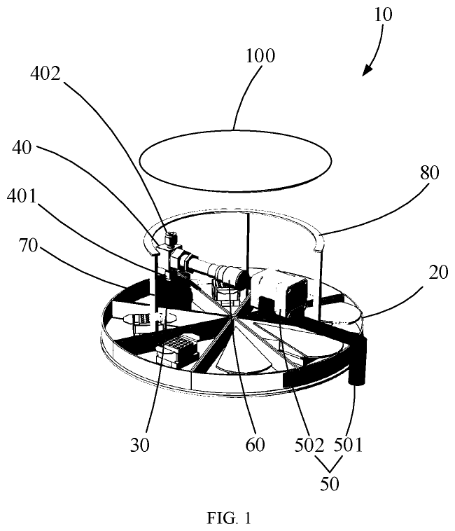

As shown in FIG. 1 and FIG. 2, FIG. 1 and FIG. 2 are a basic structural schematic diagram of an evaporation source device provided by the embodiment of the present application and a cross-sectional view of a vacuum box provided by the embodiment of the present application, respectively. The evaporation source device includes a vacuum chamber 10, and a pedestal 20, at least one vacuum box 30, and at least one control valve 40 that are disposed in the vacuum chamber 10; at least one of the vacuum boxes 30 is disposed on the pedestal 20, a crucible 301 is disposed in the vacuum box 30, and the crucible 301 is used to generate an evaporation source; the vacuum box 30 is connected with the control valve 40; wherein the control valve 40 includes a first nozzle 401 and a second nozzle 402 disposed oppositely, the first nozzle 401 communicates with the vacuum box 30, and the second nozzle 402 communicates with the vacuum chamber 10.

It can be understood that by setting the crucible 301 in the vacuum box 30 in the embodiment of the present application, splashing raw materials can be prevented from being evaporated to a substrate 100; by connecting the vacuum box 30 with the control valve 40, the control valve 40 includes the first nozzle 401 and the second nozzle 402 disposed oppositely, the first nozzle 401 communicates with the vacuum box 30, the second nozzle 402 communicates with the vacuum chamber 10; the evaporation source generated in the vacuum box 30 enters the control valve 40 from the first nozzle 401, and then enters the vacuum chamber 10 through the second nozzle 402 of the control valve 40; in the present application, by changing a degree of opening and closing of the control valve 40, a vapor flow entering the vacuum chamber 10 can be controlled, so as to prevent a vapor flow from being too large and the vacuum degree in the vacuum chamber 10 is greatly reduced, so that a thickness of a coating film can be controlled at all times during an evaporation coating process, and quality of the coating film can be improved; it can also make the raw materials react uniformly and prevent generation of white particles from affecting roughness of the thin film.

It can be understood that since the vacuum box 30 is evacuated, the present application can limit the vapor flow by changing the opening and closing degree of the control valve 40 by placing the crucible 301 in the vacuum box 30; if the crucible 301 is placed in the vacuum chamber 10 directly, there is no way to limit the vapor flow generated by an evaporation reaction. Specifically, the crucible 301 is disposed in the vacuum box 30, if gas generated is too much, the vacuum degree in the vacuum box 30 will decrease, but a change in the vacuum degree in the vacuum box 30 will not affect the vacuum degree in the vacuum chamber 10; therefore, it will not affect the quality of the coating film as long as there is no impurities in the vacuum box 30. In addition, it should be noted that the control valve 40 may be any high-precision valve or valve structure.

Referring to FIG. 2, in an embodiment, the vacuum box 30 includes a box body 302 and a box cover 303, the box cover 303 is sealed and coupled with the box body 302, and the first nozzle 401 is communicated with the vacuum box 30 through the box cover 303.

It can be understood that the vacuum box 30 provided in the embodiment is composed of the box body 302 and the box cover 303, wherein the box cover 303 and the box body 302 are sealed and coupled by a bolt 304, and the raw materials to be evaporated can be placed in the crucible 301 by disassembling or assembling the bolt 304 to separate the box cover 303 from or seal the box cover 303 with the box body 302. In addition, since the gas generated during the evaporation process will move upward, in the embodiment, the first nozzle 401 of the control valve 40 is communicated with the box cover 303, so that the gas can enter the control valve 40 upward through the first nozzle 401 on the box cover 303 directly.

In an embodiment, the vacuum box 30 includes a conductive member 31, the conductive member 31 includes a conductive rod 305 and a ceramic 306 disposed around the conductive rod 305, and the conductive rod 305 is sealed and connected with the box body 302 through the ceramic 306.

It should be noted that the conductive member 31 is a structure used to introduce a current into an interior of the vacuum box 30 from an outside and ensure that the interior of the vacuum box 30 is still a high vacuum. Wherein, the conductive rod 305 is a part of the conductive member 31 and is generally made of copper, and the conductive rod 305 can conduct the current. In the embodiment, the ceramic 306 is used to wrap the conductive rod 305 to prevent the current on the conductive rod 305 from being directly introduced into the box body 302 of the vacuum box 30, that is, the ceramic 306 plays an insulating role.

In an embodiment, the conductive rod 305 includes a first conductive part 3051 and a second conductive part 3052 continuously disposed, the first conductive part 3051 is located outside a box of the vacuum box 30, and the second conductive part 3052 is located in the box of the vacuum box 30.

It can be understood that in this embodiment, the conductive rod 305 is divided into the first conductive part 3051 and the second conductive part 3052, wherein the first conductive part 3051 is located outside the box of the vacuum box 30 and is used to connect a current outside the box; the second conductive part 3052 is located in the box of the vacuum box 30 and is used to guide the current on the first conductive part 3051 into the box of the vacuum box 30.

It should be noted that the first conductive part 3051 and the second conductive part 3052 are continuous, a connection between the first conductive part 3051 and the second conductive part 3052 is wrapped with the ceramic 306, and the ceramic 306 is soldered to the body box 302 of the vacuum box 30 by a solder, so as to achieve a vacuum feed.

In an embodiment, the vacuum chamber 10 is disposed with a power module 11 (as shown in FIG. 4); wherein the first conductive part 3051 is electrically connected to the power module 11, and the second conductive part 3052 is electrically connected to the crucible 301.

It can be understood that in the embodiment, the power module 11 (as shown in FIG. 4) is disposed in the vacuum chamber 10 to supply power to the vacuum box 30, wherein the vacuum box 30 introduces a current generated by the power module 11 into the box through the first conductive part 3051 of the conductive member 31, and then introduces the current into the crucible 301 through the second conductive part 3052 of the conductive member 31, thereby heating the crucible 301 to generate the evaporation source.

In an embodiment, a width of the second conductive part 3052 is greater than a width of the first conductive part 3051 in a direction perpendicular to the extending direction of the conductive rod 305.

It can be understood that in this embodiment, by setting the width of the second conductive part 3052 greater than the width of the first conductive part 3051, a contact area between the second conductive part 3052 and the crucible 301 can be increased, and a better conduction effect can be achieved.

Continuing to refer to FIG. 1, in an embodiment, the vacuum chamber 10 is disposed with a motor member 50; the motor member 50 includes a motor support 501 and a vacuum motor 502, the motor support 501 is located on the pedestal 20, and the vacuum motor 502 is located on the motor support 501; wherein the vacuum motor 502 is sealed and connected to the control valve 40 through a transmission mechanism 60.

It should be noted that the vacuum motor 502 is used to change the degree of opening and closing of the control valve 40. In different time periods, amounts of gas generated in the vacuum box 30 are different, and therefore, restriction requirements on the gas flow are also different. Therefore, the opening and closing degree of the control valve 40 needs to be changed by the vacuum motor 502; when the reaction rate is too fast, an opening of the control valve 40 is made smaller; when the reaction rate is too slow, the opening of the control valve 40 is made larger, so that the vacuum environment in the vacuum chamber 10 is better, and the quality of the coating film is improved. Specifically, the vacuum motor 502 is an electric motor used to drive a motor of the control valve 40 so that the motor of the control valve 40 can rotate; the vacuum motor 502 is similar to a motor.

It should be noted that a motor used in the evaporation source device in the prior art is not vacuum, and a part of liquid grease in the motor easily volatilizes, causing pollution to the substrate 100. In this embodiment, the liquid grease will not volatilize by using the vacuum motor 502, and the substrate 100 will not be polluted, and the quality of the coating film is improved.

In an embodiment, the transmission mechanism 60 is a casing, and the control valve 40 is a corrugated metering valve. It can be understood that the vacuum motor 502 is sealed and connected to the control valve 40 through the sleeve to prevent the gas in the vacuum box 30 from leaking out through the vacuum motor 502 and to prevent affecting the vacuum degree in the vacuum chamber 10.

In an embodiment, at least three support rods 70 are disposed on the pedestal 20, and a bearing platform 80 is disposed on a side of the at least three support rods 70 away from the pedestal 20; and the bearing platform 80 is located on a side of the second nozzle 402 away from the first nozzle 401.

It can be understood that an external power module 11 (as shown in FIG. 4) conducts a high current into the crucible 301 in the vacuum box 30 through the conductive member 31 to heat the crucible 301, and gas thus generated enters the control valve 40 through the first nozzle 401 on the box cover 303 and then enters the vacuum chamber 10 through the second nozzle 402 of the control valve 40; the bearing platform 80 is used for carrying the substrate 100, and finally the thin film is deposited on the substrate 100.

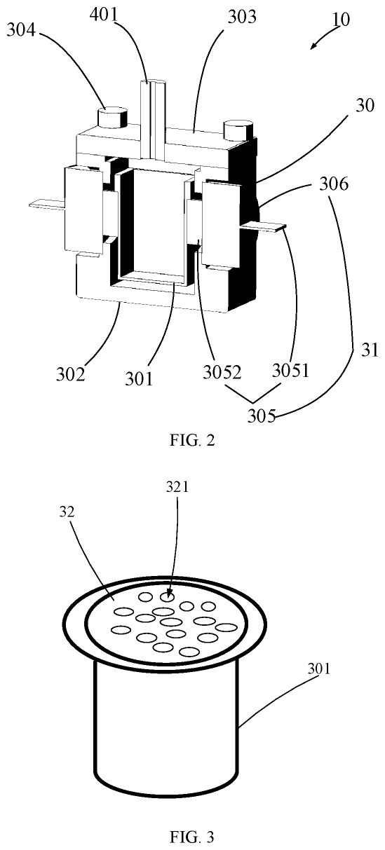

In an embodiment, as shown in FIG. 3, FIG. 3 is a schematic diagram of placing a graphite block on the crucible provided by the embodiment of the present application; specifically, the graphite block 32 is disposed in the vacuum box 30, and the graphite block 32 is located on a side of the crucible 301 close to the first nozzle 401; wherein in a direction from the crucible 301 to the first nozzle 401, a plurality of through holes 321 are defined on the graphite block 32.

It can be understood that in the embodiment, by setting the graphite block 32 on the side of the crucible 301 close to the first nozzle 401, gas generated in the crucible 301 flows out through the through holes 321 on the graphite block 32, which can play a role of making heat uniform.

In an embodiment, a material of the crucible 301 is alumina (Al₂O₃) or pyrolytic boron nitride (PBN). A thermocouple (not shown) is disposed on the box body 302 of the vacuum box 30 to monitor a temperature of the crucible 301 in real time. A reflective plate (not shown) is disposed outside the vacuum box 30 to maintain a temperature of the vacuum box 30. A cooling water interlayer (not shown) is disposed in an outer wall of the reflecting plate to cool the evaporation source.

In an embodiment, a shape of the first conductive part 3051 is sheet shaped, and a shape of the second conductive part 3052 is cylindrical. Please refer to FIG. 4, FIG. 4 is a side view of the vacuum box provided in the embodiment of the present application placed in the vacuum chamber. It can be clearly seen from FIG. 4 that the pedestal 20 clamps the first conductive part 3051 to fix the vacuum box 30; therefore, by setting the first conductive part 3051 in a sheet shape, it is more conducive to clamping; the second conductive part 3052 is disposed in a cylindrical shape, and a bottom surface or a top surface of the cylindrical shape is electrically connected to the crucible 301, which increases the contact area between the second conductive part 3052 and the crucible 301 and improves a conduction effect of the current.

It should be noted that at least one vacuum box 30 is disposed on the pedestal 20. Specifically, please refer to FIG. 5, FIG. 5 is a top view of the vacuum box placed in the vacuum chamber provided by the embodiment of the present application; it can be clearly seen from FIG. 5 that eight vacuum boxes 30 can be disposed on the pedestal 20, and only one vacuum box 30 is drawn as an example for illustration in FIG. 5. A probe position 90 is disposed on the pedestal 20, and the probe position 90 is used for placing a probe (not shown in the figure), and the probe is a mechanism for detecting gas flow.

An embodiment of the present application further provides an evaporation source system including the above-mentioned evaporation source device and a substrate placed in the evaporation source device. Please refer to FIG. 1 to FIG. 5 and related descriptions for basic structures of the evaporation source device, which is not repeated here.

To sum up, the embodiments of the present application provide the evaporation source device which includes the vacuum chamber, and the pedestal, the at least one vacuum box, and the at least one control valve that are disposed in the vacuum chamber; and at least one of the vacuum boxes is disposed on the pedestal, the crucible is disposed in the vacuum box; the vacuum box is connected with the control valve; wherein the control valve includes the first nozzle and the second nozzle disposed oppositely, the first nozzle communicates with the vacuum box, and the second nozzle communicates with the vacuum chamber. In the present application, by setting the crucible in the vacuum box, the splashing raw materials can be prevented from being evaporated to the substrate; by allowing the evaporation source generated in the vacuum box to enter the vacuum chamber through the control valve, the gas flow can be controlled by changing the opening and closing degree of the control valve, so as to control the thickness of the coating film at all times during the evaporation coating process and improve the quality of the coating film; it can also make the raw materials react uniformly, prevent the generation of white particles from affecting the roughness of the thin film, and solve the technical problem that the gas flow of the evaporation source device in the prior art is uncontrollable and the material evaporates too fast, which leads to the decrease in the vacuum degree in the vacuum chamber and affects the quality of the coating film; in addition, and solve the technical problem that the raw materials splash during the evaporation process and the roughness of the thin film formed by evaporation is too high.

The evaporation source device and the evaporation source system provided by the embodiments of the present application are described in detail above. It should be understood that exemplary embodiments described herein should be regarded as descriptive only, and are used to aid the understanding of the method and the core idea of the present application, but not to limit the present application.

What is claimed is:

1. An evaporation source device, comprising:
a vacuum chamber;
a pedestal disposed in the vacuum chamber;
at least one vacuum box disposed on the pedestal and in the vacuum chamber, a crucible disposed in the vacuum box; and
at least one control valve disposed in the vacuum chamber, the vacuum box connected with the control valve;
wherein the control valve comprises a first nozzle and a second nozzle disposed oppositely, the first nozzle communicates with the vacuum box, and the second nozzle communicates with the vacuum chamber.

2. The evaporation source device according to claim 1, wherein the vacuum box comprises a box body and a box cover, the box cover is sealed and coupled with the box body, and the first nozzle is communicated with the vacuum box through the box cover.

3. The evaporation source device according to claim 2, wherein the vacuum box comprises a conductive member, the conductive member comprises a conductive rod and a ceramic disposed around the conductive rod, and the conductive rod is sealed and connected to the box body through the ceramic.

4. The evaporation source device according to claim 3, wherein the conductive rod comprises a first conductive part and a second conductive part continuously disposed, the first conductive part is located outside a box of the vacuum box, and the second conductive part is located in the box of the vacuum box.

5. The evaporation source device according to claim 4, wherein a power module is disposed in the vacuum chamber; and
wherein the first conductive part is electrically connected to the power module, and the second conductive part is electrically connected to the crucible.

6. The evaporation source device according to claim 5, wherein a width of the second conductive part is greater than a width of the first conductive part in a direction perpendicular to an extending direction of the conductive rod.

7. The evaporation source device according to claim 1, wherein a motor member is disposed in the vacuum chamber, and the motor member comprises a motor support and a vacuum motor; the motor support is located on the pedestal, and the vacuum motor is located on the motor support; and
wherein the vacuum motor is sealed and connected with the control valve through a transmission mechanism.

8. The evaporation source device according to claim 7, wherein the transmission mechanism is a casing, and the control valve is a corrugated metering valve.

9. The evaporation source device according to claim 1, wherein at least three support rods are disposed on the pedestal, and a bearing platform is disposed on a side of the at least three support rods away from the pedestal; and
wherein the bearing platform is located on a side of the second nozzle away from the first nozzle.

10. The evaporation source device according to claim 1, wherein a graphite block is disposed in the vacuum box, and the graphite block is located on a side of the crucible close to the first nozzle; and
wherein in a direction from the crucible to the first nozzle, a plurality of through holes are defined on the graphite block.

11. An evaporation source system, comprising an evaporation source device and a substrate disposed in the evaporation source device, the evaporation source device comprising:
a vacuum chamber;
a pedestal disposed in the vacuum chamber;
at least one vacuum box disposed on the pedestal and in the vacuum chamber, a crucible disposed in the vacuum box; and
at least one control valve disposed in the vacuum chamber, the vacuum box connected with the control valve;
wherein the control valve comprises a first nozzle and a second nozzle disposed oppositely, the first nozzle communicates with the vacuum box, and the second nozzle communicates with the vacuum chamber.

12. The evaporation source system according to claim 11, wherein the vacuum box comprises a box body and a box cover, the box cover is sealed and coupled with the box body, and the first nozzle is communicated with the vacuum box through the box cover.

13. The evaporation source system according to claim 12, wherein the vacuum box comprises a conductive member, the conductive member comprises a conductive rod and a ceramic disposed around the conductive rod, and the conductive rod is sealed and connected to the box body through the ceramic.

14. The evaporation source system according to claim 13, wherein the conductive rod comprises a first conductive part and a second conductive part continuously disposed, the first conductive part is located outside a box of the vacuum box, and the second conductive part is located in the box of the vacuum box.

15. The evaporation source system according to claim 14, wherein a power module is disposed in the vacuum chamber; and
wherein the first conductive part is electrically connected to the power module, and the second conductive part is electrically connected to the crucible.

16. The evaporation source system according to claim 15, wherein a width of the second conductive part is greater than a width of the first conductive part in a direction perpendicular to an extending direction of the conductive rod.

17. The evaporation source system according to claim 11, wherein a motor member is disposed in the vacuum chamber, and the motor member comprises a motor support and a vacuum motor; the motor support is located on the pedestal, and the vacuum motor is located on the motor support; and
wherein the vacuum motor is sealed and connected with the control valve through a transmission mechanism.

18. The evaporation source system according to claim 17, wherein the transmission mechanism is a casing, and the control valve is a corrugated metering valve.

19. The evaporation source system according to claim 11, wherein at least three support rods are disposed on the pedestal, and a bearing platform is disposed on a side of the at least three support rods away from the pedestal; and
wherein the bearing platform is located on a side of the second nozzle away from the first nozzle.

20. The evaporation source system according to claim 11, wherein a graphite block is disposed in the vacuum box, and the graphite block is located on a side of the crucible close to the first nozzle; and
wherein in a direction from the crucible to the first nozzle, a plurality of through holes are defined on the graphite block.
